(19) United States
(12) Patent Application Publication
(10) Pub. No.: US 2025/0359014 A1
(43) Pub. Date: Nov. 20, 2025

(54) SEMICONDUCTOR MEMORY DEVICE

(71) Applicant: Samsung Electronics Co., Ltd., Suwon-si (KR)

(72) Inventors: Gyuhwan OH, Suwon-si (KR); Jinwoo HAN, Suwon-si (KR)

(73) Assignee: Samsung Electronics Co., Ltd., Suwon-si (KR)

(21) Appl. No.: 18/982,542

(22) Filed: Dec. 16, 2024

(30) Foreign Application Priority Data
May 17, 2024 (KR) 10-2024-0064807

(51) Int. Cl. H10B 12/00; H01L 23/00; H01L 25/00; H01L 25/065; H01L 25/18; H10B 80/00

(52) U.S. Cl. CPC H10B 12/30; H01L 24/08; H01L 24/80; H01L 25/0657; H01L 25/18; H01L 25/50; H10B 12/03; H10B 12/05; H10B 80/00; H01L 2224/08145; H01L 2224/80895; H01L 2224/80896; H01L 2924/1431; H01L 2924/1436

(57) ABSTRACT

The inventive concepts provide a semiconductor memory device including a first stack structure including a memory cell region, the memory cell region including a plurality of memory cells three-dimensionally arranged, the plurality of memory cells including a plurality of cell capacitors, a second stack structure including a core region at a position vertically overlapping the memory cell region, and the core region electrically connected to the memory cell region. The first stack structure comprises a first substrate, a first semiconductor pattern on the first substrate in the memory cell region, the first semiconductor pattern extending in a first direction parallel to a top surface of the first substrate, a word line surrounding the first semiconductor pattern and the word line extending in a second direction, the second direction being parallel to the top surface of the first substrate.

### CROSS-REFERENCE TO RELATED APPLICATION

This application is based on and claims priority under 35 U.S.C. § 119 to Korean Patent Application No. 10-2024-0064807, filed on May 17, 2024, in the Korean Intellectual Property Office, the disclosure of which is incorporated by reference herein in its entirety.

### BACKGROUND

The inventive concepts of the present disclosure relate to a semiconductor memory device, and more particularly, to a semiconductor memory device including a plurality of memory cells which are three-dimensionally arranged.

Recently, as electronics technology advances, the down-scaling of semiconductor devices has rapidly progressed. For this reason, the further miniaturization of memory cells is needed, and there are a limitations in implementing high integration solutions and maintaining reliability in conventional memory cells. Therefore, it is required to develop semiconductor memory devices having structures where memory cells are easily miniaturized and may be highly integrated.

### SUMMARY

Various example embodiments of inventive concepts provide a semiconductor memory device having a structure where electrical and structural stability is enhanced.

Various example embodiments of the inventive concepts are not limited to the previously mentioned discussion, but other example embodiments not described herein will be clearly understood by those of ordinary skill in the art from descriptions below.

Various example embodiments of the inventive concepts provide the following semiconductor memory device.

A semiconductor memory device according to various example embodiments includes a first stack structure including a memory cell region, the memory cell region including a plurality of memory cells three-dimensionally arranged, the plurality of memory cells including a plurality of cell capacitors, a second stack structure including a core region at a position vertically overlapping the memory cell region, and the core region electrically connected to the memory cell region. The first stack structure comprises a first substrate, a first semiconductor pattern on the first substrate in the memory cell region, the first semiconductor pattern extending in a first direction parallel to a top surface of the first substrate, a word line surrounding the first semiconductor pattern and the word line extending in a second direction, the second direction being parallel to the top surface of the first substrate, a bit line connected to a first end portion of the first semiconductor pattern, the bit line extending in a third direction perpendicular to the top surface of the first substrate, and a thickness in the third direction of the first end portion of the first semiconductor pattern differs from a thickness in the third direction of a second end portion of the first semiconductor pattern, the second end portion being opposite the first end portion in the first direction.

A semiconductor memory device according to various example embodiments includes a first stack structure including a plurality of memory cells on a first substrate, the plurality of memory cells arranged apart from each other in a vertical direction, the vertical direction being perpendicular to a top surface of the first substrate, and a second stack structure on the first stack structure including a core region on a second substrate, the core region vertically overlapping each of the plurality of memory cells and electrically connected to the plurality of memory cells. The plurality of memory cells each comprise a plurality of first semiconductor patterns extending in a first direction, the first direction being parallel to the top surface of the first substrate, each of the plurality of first semiconductor patterns comprise a channel region, a first impurity region, and a second impurity region, the channel region is between the first and second impurity regions in the first direction, and a width of each of the first semiconductor patterns in a vertical direction decreases from the second impurity region, through the channel region, and through the first impurity region.

A semiconductor memory device according to various example embodiments includes a first substrate, a plurality of first semiconductor patterns on the first substrate extending in a first direction, the first direction being parallel to a top surface of the first substrate, each of the plurality of first semiconductor patterns including a first impurity region, a second impurity region, and a channel region, the channel region being between the first impurity region and the second impurity region, a word line on at least a portion of each of the plurality of first semiconductor patterns and extending in a second direction, the second direction being parallel to the top surface of the first substrate, a bit line extending in a third direction, the third direction being perpendicular to the top surface of the first substrate, the bit line connected to first end portions of the plurality of first semiconductor patterns included in the first impurity region, a plurality of cell capacitors respectively connected to second end portions of the plurality of first semiconductor patterns included in the second impurity region, and a second substrate at a vertical level which is higher than the first substrate. A thickness in the third direction of the second impurity region is equal to a thickness in the third direction of each of the plurality of cell capacitors, and the channel region and the first impurity region have a tapered shape where a thickness thereof in the third direction decreases towards the bit line.

### BRIEF DESCRIPTION OF THE DRAWINGS

Various example embodiments will be more clearly understood from the following detailed description taken in conjunction with the accompanying drawings in which:

FIG. 1 is a block diagram for describing a semiconductor memory device according to various example embodiments;

FIG. 2 is a circuit diagram illustrating a memory cell array illustrated in FIG. 1;

FIG. 3 is a circuit diagram illustrating an antifuse cell array illustrated in FIG. 1;

FIG. 4 is a perspective view illustrating a semiconductor memory device according to various example embodiments;

FIG. 5 is a schematic perspective view illustrating a memory cell region of a first stack structure of FIG. 4;

FIG. 6 is a cross-sectional view taken along line A1-A1′ of FIG. 5;

FIG. 7 is a cross-sectional view taken along line B1-B1′ of FIG. 5;

FIG. 8 is an enlarged view of a region CX1 of FIG. 6;

FIG. 9 is a layout diagram schematically illustrating a semiconductor memory device according to various example embodiments;

FIG. 10 is a cross-sectional view illustrating a semiconductor memory device according to various example embodiments;

FIG. 11 is a cross-sectional view illustrating a semiconductor memory device according to various example embodiments; and

FIGS. 12A, 12B, 13A, 13B, 14A, 14B, 15A, 15B, 16, 17, 18A, 18B, 19A, and 19B are schematic views illustrating a method of manufacturing a semiconductor memory device, according to various example embodiments.

### DETAILED DESCRIPTION

Hereinafter, various example embodiments will be described in detail with reference to the accompanying drawings. Like reference numerals refer to like elements in the drawings, and their repeated descriptions are omitted.

Various example embodiments are provided so that this disclosure will be thorough and complete, and will fully convey the concept of the inventive concepts to one of ordinary skill in the art. However, this does not limit the inventive concepts within specific embodiments and it should be understood that the inventive concepts covers all the modifications, equivalents, and replacements within the idea and technical scope of the inventive concepts. In describing the inventive concepts, if a detailed description of known techniques associated with the inventive concepts unnecessarily obscure the gist of the inventive concepts, it is determined that the detailed description thereof will be omitted.

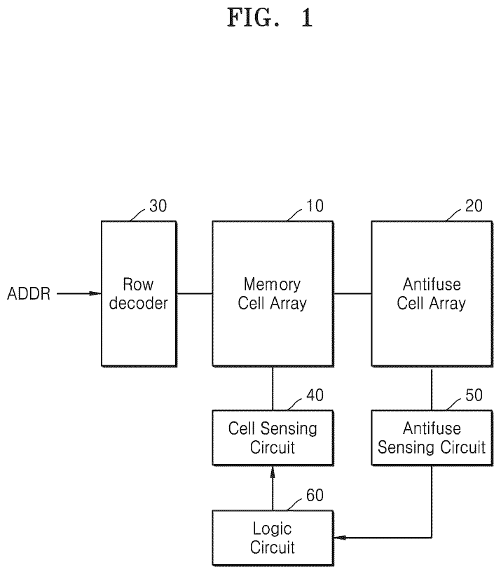

FIG. 1 is a block diagram schematically illustrating a semiconductor memory device 1 according to various example embodiments.

Referring to FIG. 1, the semiconductor memory device 1 may include a memory cell array 10, an antifuse cell array 20, a row decoder 30, a cell sensing circuit 40, an antifuse sensing circuit 50, and a logic circuit 60.

The memory cell array 10 may include a plurality of word lines and a plurality of memory cells connected to the plurality of word lines. The plurality of memory cells may be arranged to configure a column and a row. The plurality of memory cells may each be configured with dynamic random access memory (DRAM). The plurality of word lines of the memory cell array 10 may be connected to the row decoder 30.

The antifuse cell array 20 may include a plurality of antifuse cells connected between a plurality of antifuse word lines and a plurality of antifuse bit lines. The plurality of antifuse cells may store information about a fail cell included in the memory cell array 10. For example, address data of the fail cell may be electrically programmed in the antifuse cells.

The row decoder 30 may decode an address ADDR input from the outside to select a word line, and data may be read from an antifuse cell connected to the selected word line and a memory cell connected to the selected word line.

The cell sensing circuit 40 may select some bit lines from among the bit lines of the memory cell array 10 in response to a control signal provided from the logic circuit 60.

The antifuse sensing circuit 50 may sense fail cell information stored in the antifuse cells of the antifuse cell array 20 connected to the selected word line and may amplify the fail cell information. The antifuse sensing circuit 50 may provide the logic circuit 60 with a fail column address read from the antifuse cell array 20.

The logic circuit 60 may determine whether the address ADDR input from the outside matches an address of the fail cell, based on the address of the fail cell stored in each of the plurality of antifuse cells. When the address ADDR input from the outside matches the address of the fail cell, the logic circuit 60 may read the fail cell information from an antifuse cell corresponding to the fail cell to provide to the outside.

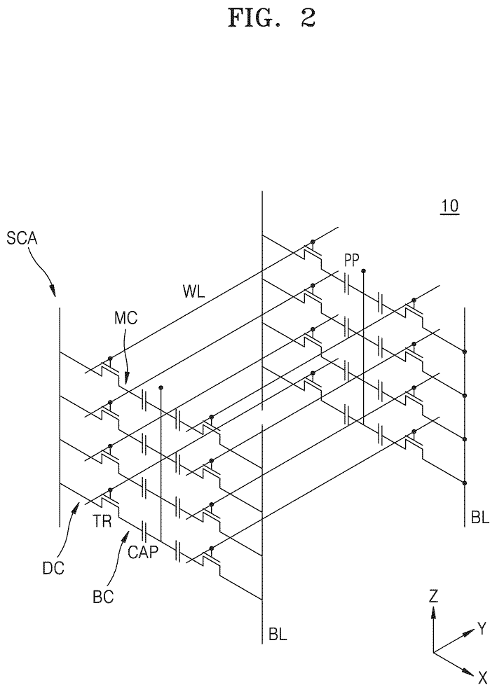

FIG. 2 is a circuit diagram illustrating the memory cell array 10 illustrated in FIG. 1.

Referring to FIG. 2, the memory cell array 10 may include a plurality of sub cell arrays SCA. The plurality of sub cell arrays SCA may be arranged apart from one another in a second horizontal direction (a Y direction).

Each of the plurality of sub cell arrays SCA may include a plurality of bit lines BL, a plurality of word lines WL, and a plurality of memory cells MC. Each of the plurality of memory cells MC may include one cell transistor TR and one cell capacitor CAP connected thereto. Each of the plurality of memory cells MC may have a one transistor-one capacitor (1T1C) structure.

The plurality of word lines WL may extend in the second horizontal direction (the Y direction) and may be arranged apart from one another in a first horizontal direction (an X direction) and a vertical direction (a Z direction). The plurality of bit lines BL may extend in the vertical direction (the Z direction) and may be arranged apart from one another in the first horizontal direction (the X direction) and the second horizontal direction (the Y direction). One cell transistor TR may be disposed between one word line WL and one bit line BL.

A gate of the cell transistor TR may be connected to a word line WL, and a source of the cell transistor TR may be connected to a bit line BL through a first contact DC. The cell transistor TR may be connected to the cell capacitor CAP through a second contact BC. A drain of the cell transistor TR may be connected to a first electrode of the cell transistor CAP through the second contact BC, and a second electrode of the cell capacitor CAP may be connected to a plate electrode PP.

In one sub cell array SCA, a plurality of cell transistors TR may be disposed at positions overlapping each other in the vertical direction (the Z direction). In one sub cell array SCA, a plurality of cell capacitors CAP may be disposed at positions overlapping each other in the vertical direction (the Z direction). One cell transistor TR and one cell capacitor CAP may be arranged in parallel at the same vertical level, and a memory cell MC configured with one cell transistor TR and one cell capacitor CAP may be stacked in plurality in the vertical direction (the Z direction). A storage capacity of the sub cell array SCA may be changed based on the number of layers (for example, the number of layers or the number of cell capacitors CAP) or the number of memory cells MC stacked in the vertical direction (the Z direction).

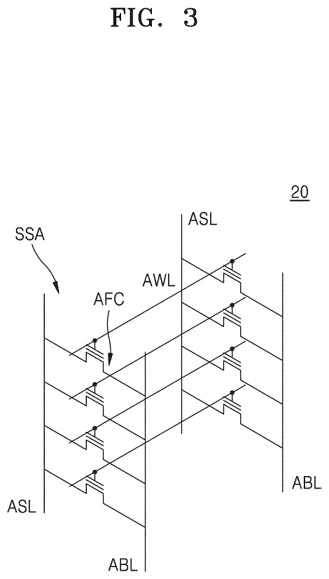

FIG. 3 is a circuit diagram illustrating the antifuse cell array 20 illustrated in FIG. 1.

Referring to FIG. 3, the antifuse cell array 20 may include a plurality of antifuse sub cell arrays SAA. The plurality of antifuse sub cell arrays SAA may be arranged apart from one another in the second horizontal direction (the Y direction).

Each of the plurality of antifuse sub cell arrays SAA may include a plurality of antifuse bit lines ABL, a plurality of antifuse word lines AWL, a plurality of antifuse source lines ASL, and a plurality of antifuse cells AFC.

The plurality of antifuse cells AFC may be connected between the plurality of antifuse word lines AWL and the plurality of antifuse bit lines ABL. In some example embodiments, the plurality of antifuse cells AFC may include a non-volatile memory device of a charge trapping type. A gate of the antifuse cell AFC may be connected to the antifuse word line AWL, a source of the antifuse cell AFC may be connected to the antifuse source line ASL, and a drain of the antifuse cell AFC may be connected to the plurality of antifuse bit lines ABL.

In one antifuse sub cell array SAA, a plurality of antifuse cells AFC may be disposed at positions overlapping each other in the vertical direction (the Z direction). In some example embodiments, the plurality of antifuse cells AFC may be formed together in at least a portion of a process of forming the cell transistor TR of the memory cell array 10. In some example embodiments, the number of antifuse cells AFC (for example, the number of layers) stacked in the vertical direction (the Z direction) may be the same as the number of cell capacitors CAP (for example, the number of layers) stacked in the vertical direction (the Z direction). In some example embodiments, the number of antifuse cells AFC (for example, the number of layers) stacked in the vertical direction (the Z direction) may be less than the number of cell capacitors CAP (for example, the number of layers) stacked in the vertical direction (the Z direction).

In some example embodiments, the plurality of antifuse cells AFC may include a non-volatile memory device of a charge trapping type, and the plurality of antifuse cells AFC may have a relatively high first threshold voltage in a programmed state (for example, after a program operation) and may have a second threshold voltage which is lower than the first threshold voltage in a non-programmed state.

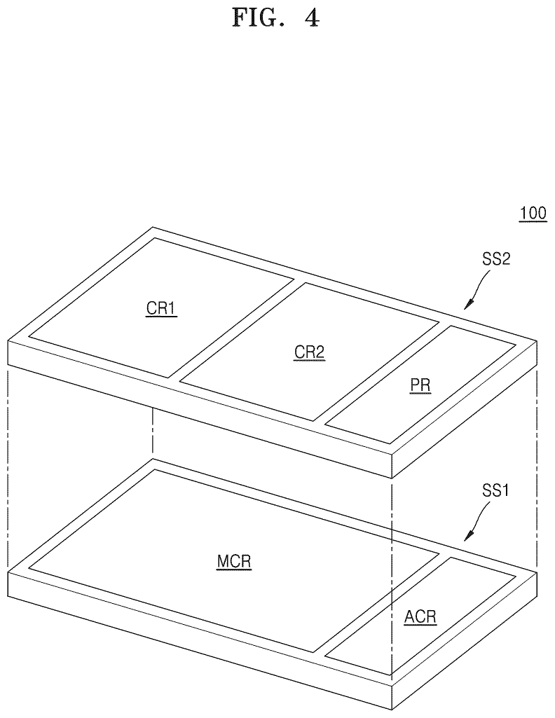

FIG. 4 is a perspective view illustrating a semiconductor memory device 100 according to embodiments.

Referring to FIG. 4, the semiconductor memory device 100 may have a structure where a first stack structure SS1 and a second stack structure SS2 are stacked in a vertical direction. For example, the first stack structure SS1 and the second stack structure SS2 may be disposed at different vertical levels. In FIG. 4, for convenience of understanding, a state where the first stack structure SS1 is apart from the second stack structure SS2 is illustrated, but the semiconductor memory device 100 may have a structure where a bottom surface of the second stack structure SS2 is attached on a top surface of the first stack structure SS1.

The first stack structure SS1 may include a memory cell region MCR and an antifuse array region ACR. The memory cell region MCR may be a region where the memory cell array 10 described above with reference to FIGS. 1 and 2 is disposed. For example, bit lines, word lines, and memory cells may be disposed in the memory cell region MCR. The antifuse array region ACR may be a region where the antifuse cell array 20 described above with reference to FIGS. 1 and 3 is disposed. The antifuse array region ACR may be disposed at one side of the memory cell region MCR. For example, antifuse bit lines, antifuse word lines, and antifuse cells may be disposed in the antifuse array region ACR.

The second stack structure SS2 may include a first core region CR1, a second core region CR2, and a peripheral circuit region PR. The first core region CR1 and the second core region CR2 may be disposed at positions vertically overlapping the memory cell region MCR and may include core circuits electrically connected to the memory cell region MCR. In various example embodiments, the first core region CR1 may include a plurality of sense amplifiers, and the sense amplifiers may be electrically connected to the bit lines included in the first stack structure SS1. In various example embodiments, the second core region CR2 may include a plurality of sub word line drivers, and the sub word line drivers may be electrically connected to the word lines included in the first stack structure SS1.

The peripheral circuit region PR may be disposed at a position vertically overlapping the antifuse array region ACR. The peripheral circuit region PR may include a control signal generating circuit for controlling a sub word line driver, a control signal generating circuit for controlling the sense amplifier, and an antifuse cell sensing circuit for controlling an antifuse cell array disposed in the antifuse array region ACR. Also, the peripheral circuit region PR may further include a voltage generator which supplies an operation voltage to the sense amplifier, the sub word line driver, and the antifuse cell sensing circuit.

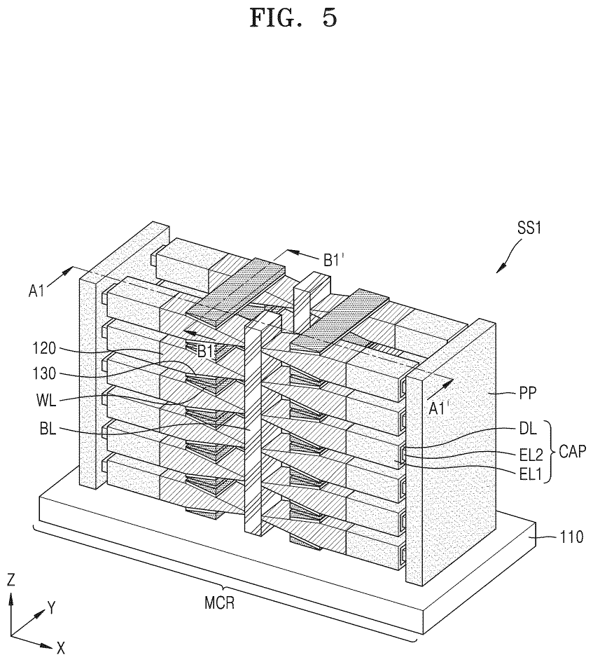

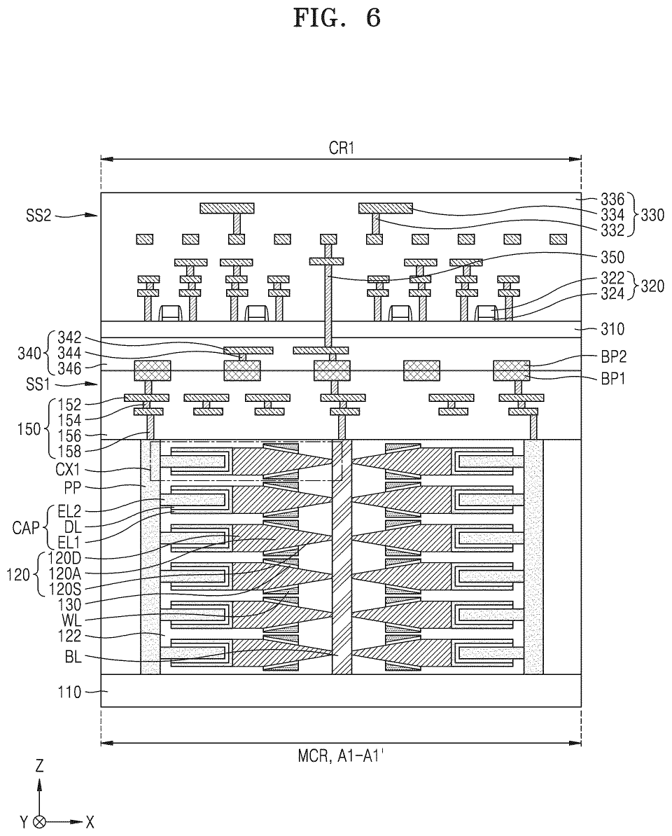

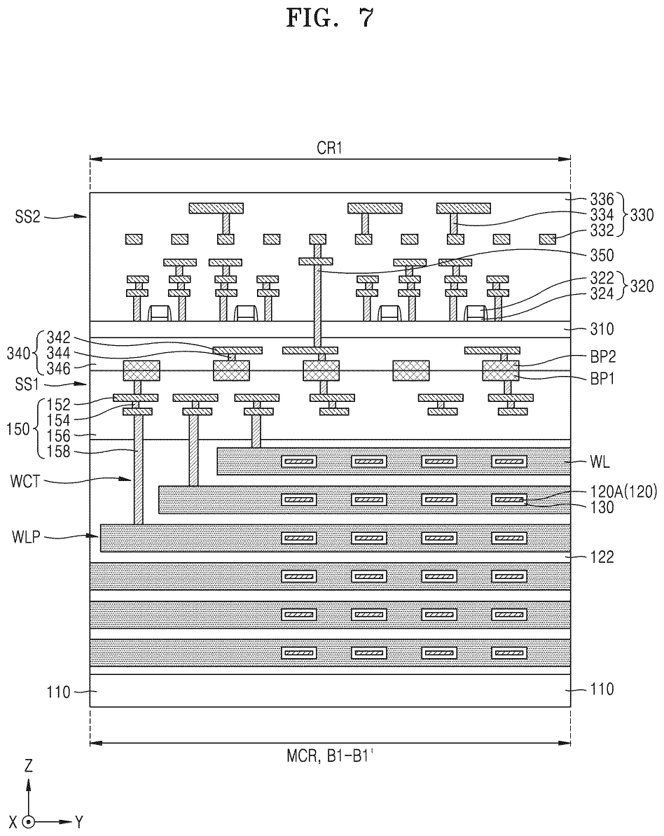

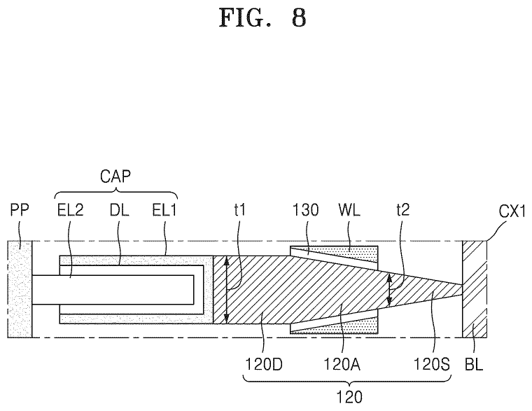

FIG. 5 is a schematic perspective view illustrating the memory cell region MCR of the first stack structure SS1 of FIG. 4. FIG. 6 is a cross-sectional view taken along line A1-A1′ of FIG. 5, and FIG. 7 is a cross-sectional view taken along line B1-B1′ of FIG. 5. FIG. 8 is an enlarged view of a region CX1 of FIG. 6.

Referring to FIGS. 5 to 8, a semiconductor memory device may include a first stack structure SS1 and a second stack structure SS2, and the second stack structure SS2 may be bonded to the first stack structure SS1 by first and second bonding pads BP1 and BP2.

The first stack structure SS1 may include a memory cell region MCR and an antifuse array region ACR (see FIG. 4), but only the memory cell region MCR is illustrated for convenience. The first stack structure SS1 may include a plurality of first semiconductor patterns 120, a plurality of bit lines BL, a plurality of word lines WL, and a cell capacitor CAP, which are disposed on a first substrate 110 in the memory cell region MCR.

In various example embodiments, the first substrate 110 may include silicon (Si), germanium (Ge), or SiGe. In various example embodiments, the first substrate 110 may include a silicon-on-insulator (SOI) substrate or a germanium-on-insulator (GeOI) substrate. However, example embodiments are not limited thereto.

In the memory cell region MCR, a plurality of first semiconductor patterns 120 may extend in a first horizontal direction (an X direction) and may be disposed apart from one another in a vertical direction (a Z direction), on the first substrate 110.

In various example embodiments, the plurality of first semiconductor patterns 120 may include, for example, an undoped semiconductor material or a doped semiconductor material. In some example embodiments, the plurality of first semiconductor patterns 120 may include polysilicon. In some example embodiments, the plurality of first semiconductor patterns 120 may include amorphous metal oxide, polycrystalline metal oxide, or a combination of amorphous metal oxide and polycrystalline metal oxide, and for example, may include at least one indium-gallium (In—Ga) oxide (IGO), indium-zinc (In—Zn) oxide (IZO), or In—Ga—Zn oxide (IGZO). However, example embodiments are not limited thereto. In some other example embodiments, the plurality of first semiconductor patterns 120 may include a two-dimensional (2D) semiconductor material, and for example, the 2D semiconductor material may include MoS₂, WSe₂, graphene, carbon nano tube, or a combination thereof. However, example embodiments are not limited thereto.

In various example embodiments, the plurality of first semiconductor patterns 120 may have a line shape or a bar shape, which extends in the first horizontal direction (the X direction). In various example embodiments, each of the plurality of first semiconductor patterns 120 may a channel region 120A, and a first impurity region 120S and a second impurity region 120D arranged in the first horizontal direction (the X direction) with the channel region 120A therebetween. The first impurity region 120S may be connected to the bit line BL, and the second impurity region 120D may be connected to the cell capacitor CAP. An ohmic metal layer including metal silicide may be further formed between the first impurity region 120S and the bit line BL and between the second impurity region 120D and the cell capacitor CAP.

In this case, in the first semiconductor pattern 120 extending in a bar shape, a thickness of the first impurity region 120S in the vertical direction (the Z direction) may be progressively changed in the first horizontal direction (the X direction). Particularly, the first impurity region 120S may have a tapered shape where a thickness thereof in the vertical direction (the Z direction) decreases progressively toward the bit line BL.

Furthermore, in the first semiconductor pattern 120 extending in a bar shape, a thickness of the second impurity region 120D in the vertical direction (the Z direction) may be intactly maintained in the first horizontal direction (the X direction), and in this case, a thickness of the second impurity region 120D in the vertical direction (the Z direction) may be substantially the same as a thickness of the cell capacitor CAP in the vertical direction (the Z direction).

The plurality of word lines WL may be disposed on top surfaces and bottom surfaces of the plurality of first semiconductor patterns 120, may extend in a second horizontal direction (a Y direction), and may be disposed apart from one another in the vertical direction (the Z direction). One of the plurality of word lines WL may surround the plurality of first semiconductor patterns 120 arranged apart from one another in the second horizontal direction (the Y direction) and may extend in the second horizontal direction (the Y direction). Two word lines WL, spaced apart from each other in the vertical direction (the Z direction), of the plurality of word lines WL may be disposed at positions overlapping each other in the vertical direction (the Z direction).

In various example embodiments, the plurality of word lines WL may include at least one of a doped semiconductor material (doped Si, doped Ge, etc.), conductive metal nitride (nitride titanium, nitride tantalum, etc.), metal (tungsten, titanium, tantalum, etc.), and a metal-semiconductor compound (tungsten silicide, cobalt silicide, titanium silicide, etc.). However, example embodiments are not limited thereto.

In various example embodiments, a gate insulation layer 130 may be disposed between the word line WL and the first semiconductor pattern 120. The gate insulation layer 130 may include at least one of a high-k dielectric material having a dielectric constant which is higher than that of silicon oxide and a ferroelectric material. In various example embodiments, the gate insulation layer 130 may include at least one material selected from among hafnium oxide (HfO), hafnium silicate (HfSiO), hafnium oxide nitride (HfON), hafnium silicon oxide nitride (HfSiON), lanthanum oxide (LaO), lanthanum aluminum oxide (LaAIO), zirconium oxide (ZrO), zirconium silicon oxide (ZrSiO), zirconium oxide nitride (ZrON), zirconium silicon oxide nitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). However, example embodiments are not limited thereto.

The plurality of bit lines BL may extend in the vertical direction (the Z direction) and may be disposed apart from one another in the second horizontal direction (the Y direction), on the first substrate 110. The plurality of bit lines BL may include one of a doped semiconductor material, conductive metal nitride, and a metal-semiconductor compound. However, example embodiments are not limited thereto.

The cell capacitor CAP may include a first electrode EL1, a capacitor dielectric layer DL, and a second electrode EL2. The first electrode EL1 may extend in the first horizontal direction (the X direction) and may be disposed apart from one another in the vertical direction (the Z direction). The first electrode EL1 may include an internal space (not shown) which extends in the first horizontal direction (the X direction), and the internal space may be filled by the capacitor dielectric layer DL and the second electrode EL2. For example, the first electrode EL1 may have a cup shape which has rotated by 90 degrees.

The capacitor dielectric layer DL may include at least one of a high-k dielectric material having a dielectric constant which is higher than that of silicon oxide and a ferroelectric material. In some example embodiments, the capacitor dielectric layer DL may include at least one material selected from among HfO, HfSiO, HfON, HfSiON, LaO, LaAIO, ZrO, ZrSiO, ZrON, ZrSiON, TaO, TiO, BaSrTiO, BaTiO, SrTiO, YO, AIO, and PbScTaO. However, example embodiments are not limited thereto.

The second electrode EL2 may fill the internal space of the first electrode EL1, and the capacitor dielectric layer DL may be disposed between the second electrode EL2 and the internal space of the first electrode EL1.

The first electrode EL1 and the second electrode EL2 may include conductive metal nitride such as a doped semiconductor material, titanium nitride, tantalum nitride, niobium nitride, or tungsten nitride, metal such as ruthenium, iridium, titanium, or tantalum, or conductive metal oxide such as iridium oxide or niobium oxide. However, example embodiments are not limited thereto.

The plate electrode PP may be disposed to extend in the vertical direction (the Z direction) and the second horizontal direction (the Y direction) at one side of the cell capacitor CAP. The second electrode EL2 of the cell capacitor CAP may be electrically connected to the plate electrode PP, and for example, may be connected to, in common, a plurality of second electrodes EL2 arranged apart from one another in the vertical direction Z and a plurality of second electrodes EL2 arranged apart from one another in the second horizontal direction (the Y direction).

A mold insulation layer 122 may be disposed between two adjacent first semiconductor patterns 120 arranged apart from each other in the vertical direction Z, between two adjacent word lines WL arranged apart from each other in the vertical direction Z, and between two adjacent first electrodes EL1 arranged apart from each other in the vertical direction Z. Also, the mold insulation layer 122 may be disposed between two bit lines BL arranged apart from each other in the second horizontal direction (the Y direction).

In various example embodiments, the mold insulation layer 122 may include silicon oxide, silicon oxynitride, silicon nitride, carbon-containing silicon oxide, carbon-containing silicon oxynitride, carbon-containing silicon nitride, or a combination thereof. However, example embodiments are not limited thereto. In various example embodiments, the mold insulation layer 122 may include a plurality of insulation layers. Here, based on a manufacturing process applied for forming a three-dimensional (3D) structure, insulation material layers formed between the plurality of bit lines BL, between the plurality of word lines WL, between the plurality of first semiconductor patterns 120, and between the plurality of cell capacitors CAP may be referred to as a mold insulation layer 122.

An upper wiring structure 150 may be disposed in the memory cell region MCR. The upper wiring structure 150 may include a wiring layer 152, a via 154, and an insulation layer 156. The upper wiring structure 150 may further include a contact 158 electrically connected to the bit line BL, the word line WL, and the plate electrode PP. Also, a first bonding pad BP1 disposed on the same plane as an uppermost surface of the insulation layer 156 may be formed on the upper wiring structure 150.

The second stack structure SS2 may include a second substrate 310, a peripheral circuit transistor 320 disposed on the second substrate 310, a front wiring structure 330 covering the peripheral circuit transistor 320 on a top surface of the second substrate 310, and a backside wiring structure 340 disposed on a bottom surface of the second substrate 310. The front wiring structure 330 may include a wiring layer 332, a via 334, and an insulation layer 336, and the backside wiring structure 340 may include a wiring layer 342, a via 344, and an insulation layer 346.

The backside wiring structure 340 may include a second bonding pad BP2 disposed on the same plane as a bottom surface of the insulation layer 346, and as the second bonding pad BP2 is connected to the first bonding pad BP1, the first stack structure SS1 may be bonded to the second stack structure SS2. In various example embodiments, the first stack structure SS1 and the second stack structure SS2 may be bonded to each other by a copper-oxide hybrid bonding process. In various example embodiments, the first bonding pad BP1 and the second bonding pad BP2 may include copper or a copper alloy. An interface between the insulation layer 156 of the upper wiring structure 150 and the insulation layer 346 of the backside wiring structure 340 may flatly extend and may be disposed on the same plane as an interface between the first bonding pad BP1 and the second bonding pad BP2.

In various example embodiments, the peripheral circuit transistor 320 may include a gate electrode 322 and a gate insulation layer 324, which are disposed in an active region of the second substrate 310. In various example embodiments, a peripheral circuit transistor 320 disposed in a first core region CR1 may include a plurality of sense amplifiers, and the sense amplifiers may be electrically connected to bit lines BL included in the first stack structure SS1. A peripheral circuit transistor 320 disposed in a second core region CR2 (see FIG. 4) may include sub word line drivers, and the sub word line drivers may be electrically connected to word lines WL included in the first stack structure SS1.

In various example embodiments, the second stack structure SS2 may further include a through silicon via 350 passing through the second substrate 310, the wiring layer 332 included in the front wiring structure 330 may be electrically connected to the wiring layer 342 included in the backside wiring structure 340 by using the through silicon via 350, and the wiring layer 342 included in the backside wiring structure 340 may be electrically connected to the wiring layer 332 included in the front wiring structure 330 through the first bonding pad BP1 and the second bonding pad BP2.

FIG. 8 is an enlarged view of a region CX1 of FIG. 6.

Referring to FIG. 8 in conjunction with FIG. 5, in the first semiconductor pattern 120 extending in a bar shape, a thickness of each of the channel region 120A and the first impurity region 120S in the vertical direction (the Z direction) may be progressively changed in the first horizontal direction (the X direction). Particularly, the channel region 120A and the first impurity region 120S may have a tapered shape where a thickness thereof in the vertical direction (the Z direction) decreases progressively toward the bit line BL. That is, a vertical cross-sectional area of each of the channel region 120A and the first impurity region 120S may decrease progressively toward the bit line BL.

Furthermore, in the first semiconductor pattern 120 extending in a bar shape, a thickness of the second impurity region 120D in the vertical direction (the Z direction) may be intactly maintained to be a first thickness t1 in the first horizontal direction (the X direction). In this case, the first thickness t1 of the second impurity region 120D in the vertical direction (the Z direction) may be substantially the same as a thickness of the cell capacitor CAP in the vertical direction (the Z direction). Moreover, as described above, because the channel region 120A and the first impurity region 120S have a tapered shape, a second thickness t2, which is a thickness of a thickest portion, of the first impurity region 120S may be less than the first thickness t1.

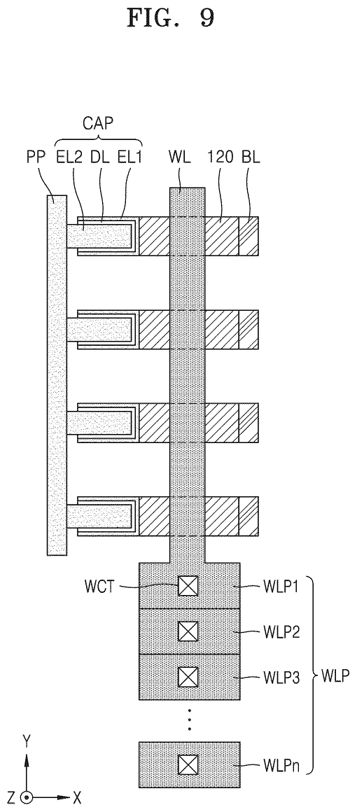

FIG. 9 is a layout diagram schematically illustrating a semiconductor memory device 100 according to embodiments.

Referring to FIG. 9 in conjunction with FIG. 7, a word line WL may extend in a second horizontal direction (a Y direction) to intersect with a first horizontal direction (an X direction) which is an extension direction of a first semiconductor pattern 120. A word line pad WLP may be disposed at an end portion of the word line WL. As illustrated in FIG. 9, a plurality of word lines WL may be arranged in order in the second horizontal direction (the Y direction), and as illustrated in FIG. 7, the plurality of word lines WL may be arranged in a staircase shape in the second horizontal direction (the Y direction).

In various example embodiments, a first word line pad WLP1 connected to a word line WL disposed at an uppermost portion, a second word line pad WLP2 connected to a word line WL disposed under an uppermost word line WL, and a third word line pad WLP3 connected to a word line WL disposed under two uppermost word lines WL may be arranged in order in the second horizontal direction (the Y direction), and in this manner, a word line pad WLPn connected to an nth word line WL may be arranged in the second horizontal direction (the Y direction) from an upper portion.

A word line contact WCT may be disposed on a top surface of each word line pad WLP, and a word line WL may be electrically connected to an upper wiring structure 150 by the word line contact WCT.

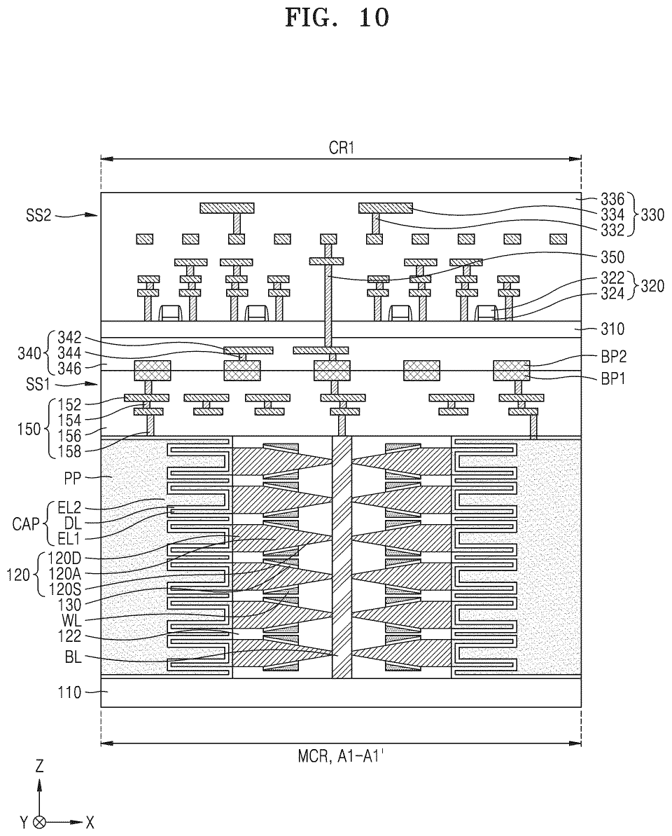

FIG. 10 is a cross-sectional view illustrating a semiconductor memory device according to various example embodiments.

Referring to FIG. 10, a cell capacitor CAP may include a first electrode EL1 having a cup shape which extends in a first horizontal direction (an X direction), a capacitor dielectric layer DL which is conformally disposed in an internal space of the first electrode EL1 and on an outer surface of the first electrode EL1, and a second electrode EL2 which fills the internal space of the first electrode EL1, and the second electrode EL2 and the plate electrode PP may be formed as one body.

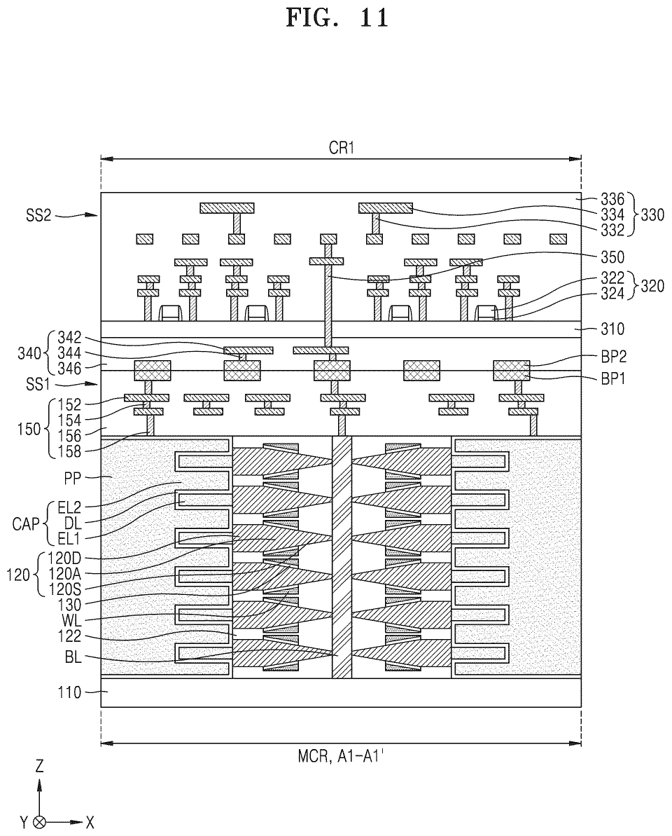

FIG. 11 is a cross-sectional view illustrating a semiconductor memory device according to embodiments.

Referring to FIG. 11, the cell capacitor CAP may include a first electrode EL1 having a pillar or bar shape which extends in a first horizontal direction (an X direction), a capacitor dielectric layer DL which is conformally disposed on an outer surface of the first electrode EL1, and a second electrode EL2 which surrounds the first electrode EL1 on the capacitor dielectric layer DL. In some example embodiments, the second electrode EL2 and the plate electrode PP may be formed as one body. In some other example embodiments, the second electrode EL2 may include a thin layer which conformally surrounds the capacitor dielectric layer DL, and the plate electrode PP may cover the second electrode EL2.

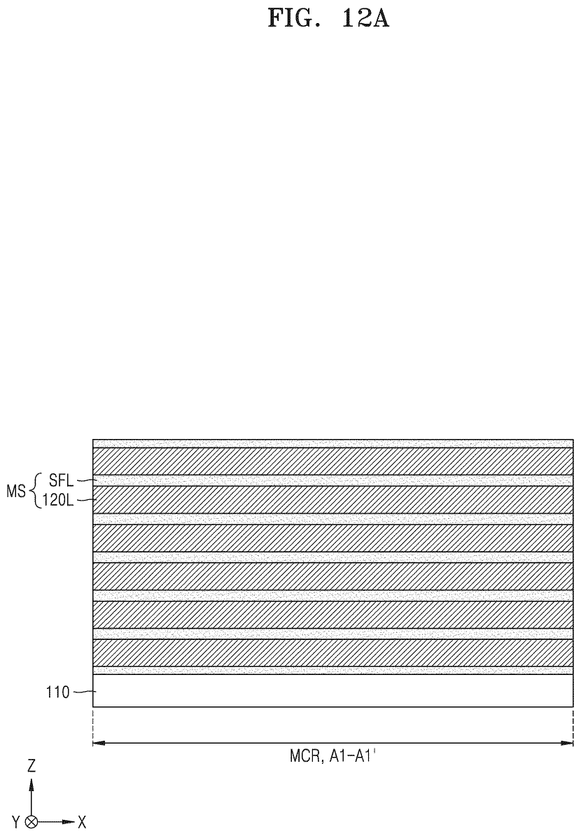

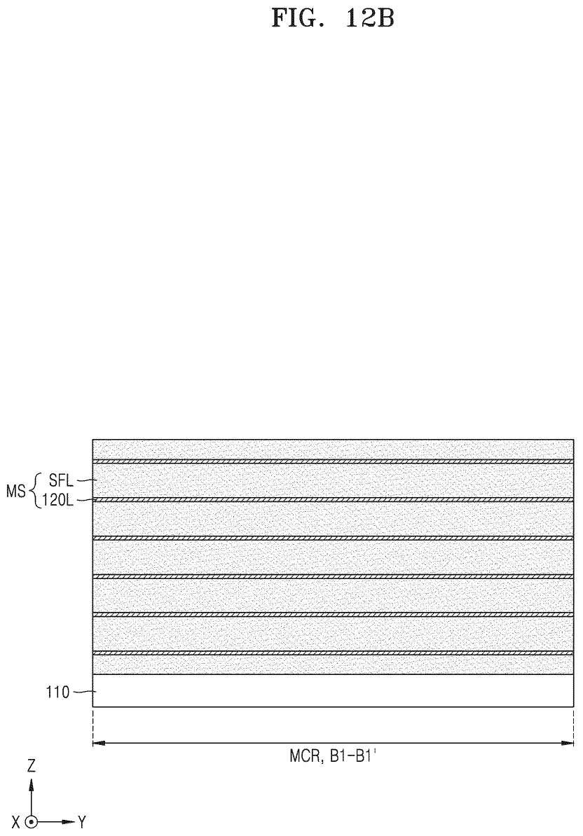

FIGS. 12A, 12B, 13A, 13B, 14A, 14B, 15A, 15B, 16, 17, 18A, 18B, 19A, and 19B are schematic views illustrating a method of manufacturing a semiconductor memory device, according to various example embodiments.

Referring to FIGS. 12A and 12B, a mold stack MS may be formed by alternately and sequentially forming a sacrificial mold layer SFL and a semiconductor layer 120L on a first substrate 110.

In various example embodiments, the sacrificial mold layer SFL and the semiconductor layer 120L may include a material having an etch selectivity with respect to each other. For example, each of the sacrificial mold layer SFL and the semiconductor layer 120L may include a single crystalline layer including a Group IV semiconductor, a Group IV-V compound semiconductor, or a Group III-V compound semiconductor, and the sacrificial mold layer SFL and the semiconductor layer 120L may include different materials. In various example embodiments, the sacrificial layer SFL may include SiGe, and the semiconductor layer 120L may include single crystalline silicon. However, example embodiments are not limited thereto. Each of the sacrificial mold layer SFL and the semiconductor layer 120L may have a thickness of tens of nm.

In various example embodiments, the sacrificial mold layer SFL and the semiconductor layer 120L may be formed by an epitaxy process. For example, the epitaxy process may include a vapor-phase epitaxy (VPE) process, a molecular beam epitaxy process, a chemical vapor deposition (CVD) process such as an ultra-high vacuum CVD (UHV-CVD) process, or a combination thereof. However, example embodiments are not limited thereto. In the epitaxy process, a liquid or gaseous precursor may be used as a precursor for forming the sacrificial mold layer SFL and the semiconductor layer 120L.

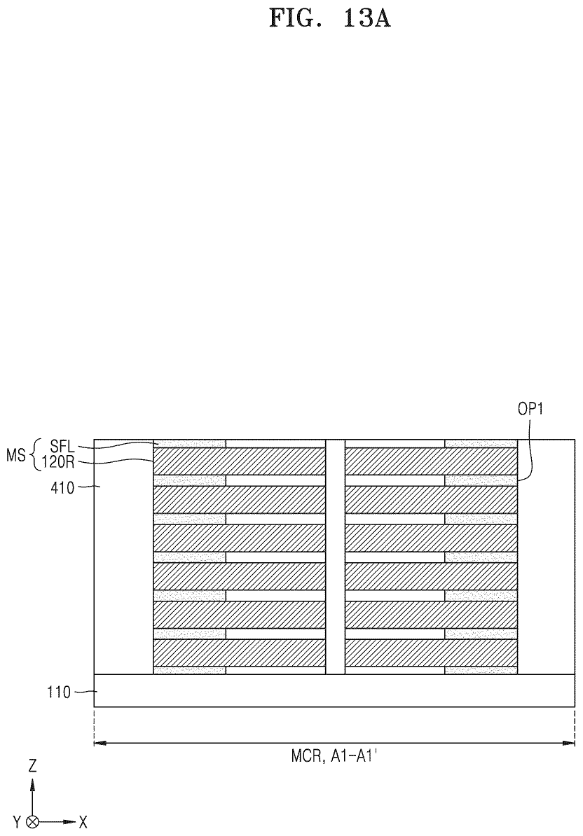

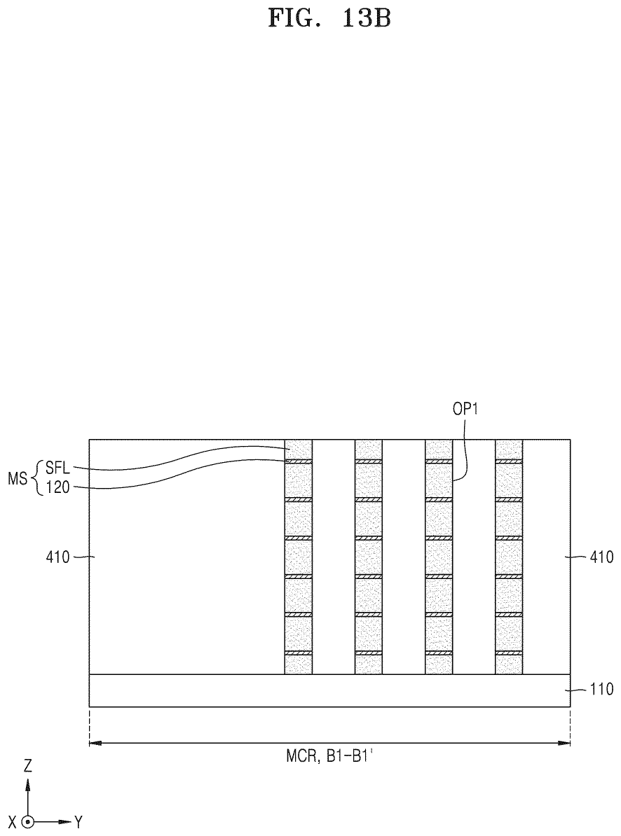

Referring to FIGS. 13A and 13B, a mask pattern (not shown) may be formed on the mold stack MS, and a first opening portion OP1 may be formed by removing a portion of the mold stack MS by using the mask pattern as an etch mask. Subsequently, a first insulation layer 410 may be formed in the first opening portion OP1.

In various example embodiments, as the first opening portion OP1 is formed, a plurality of first semiconductor patterns 120 may be formed from the semiconductor layer 120L in a memory cell region MCR. Here, the plurality of first semiconductor patterns 120 may be formed by patterning partial portions of the semiconductor layer 120L disposed in the memory cell region MCR.

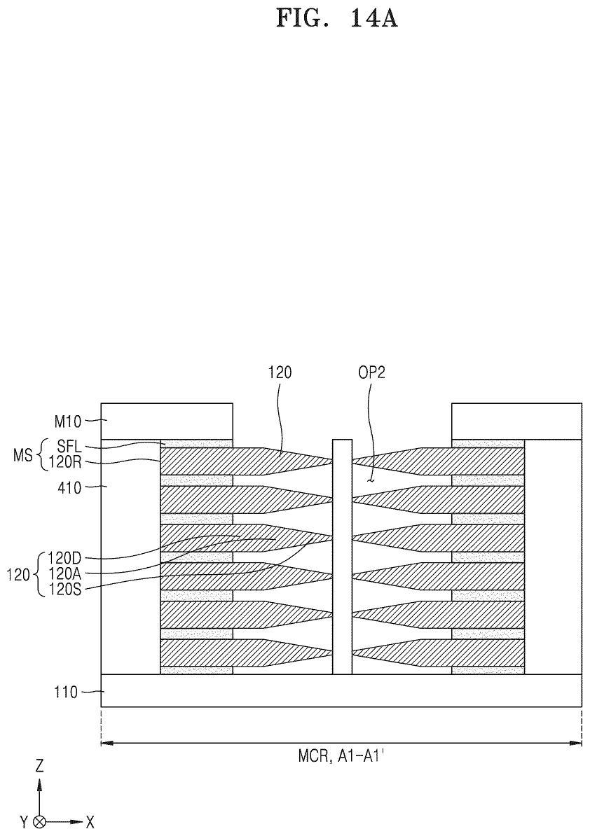

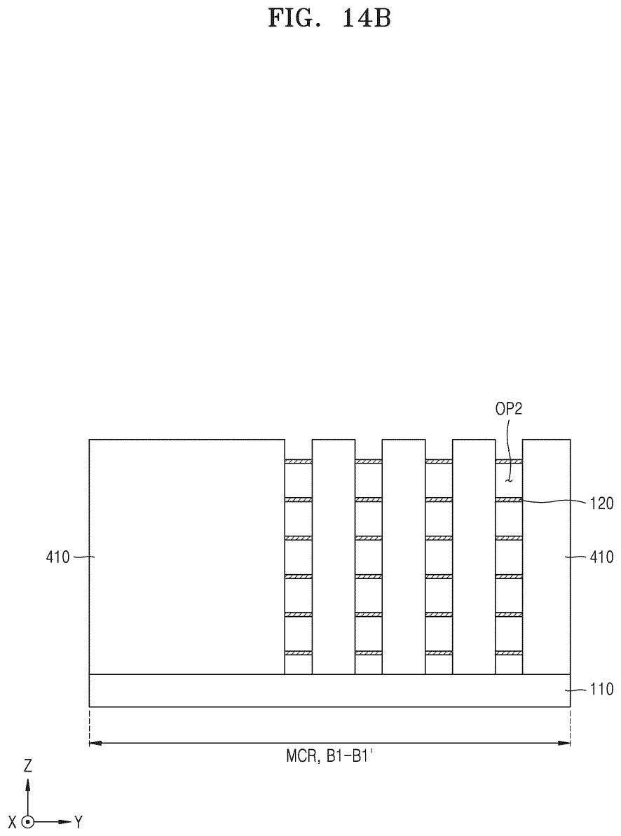

Referring to FIGS. 14A and 14B, a second opening portion OP2 may be formed between the plurality of first semiconductor patterns 120 by removing the sacrificial mold layer SFL.

In some example embodiments, as illustrated in FIG. 14A, a mask pattern M10 may be formed on the mold stack MS of the memory cell region MCR, a portion of the sacrificial mold layer SFL uncovered by the mask pattern M10 may be removed, and partial portions of the sacrificial mold layer SFL disposed at a position vertically overlapping the mask pattern M10 may not be removed and may remain. Here, a portion of the first semiconductor pattern 120 covered by the sacrificial mold layer SFL may be referred to as a residual pattern 120R. The mask pattern M10 may be disposed on a structure where the residual pattern 120R and the sacrificial mold layer SFL are alternately stacked.

In various example embodiments, a process of removing the sacrificial mold layer SFL may be a wet etching process or a pull back process. For example, the process of removing the sacrificial mold layer SFL may be an etching process using an etch selectivity between the sacrificial mold layer SFL and the semiconductor layer 120L. For example, in the wet etching process or the pull back process, an etch speed of each of the plurality of first semiconductor patterns 120 may be relatively low, and an etch speed of the sacrificial mold layer SFL may be relatively high.

In various example embodiments, a residual shape of the first semiconductor pattern 120 may have a tapered shape due to a difference between an etch speed of the semiconductor layer 120L and an etch speed of the sacrificial mold layer SFL. That is, a residual pattern 120R in a region where the sacrificial mold layer SFL is not removed may have a conformal thickness in a vertical direction (a Z direction) and may have a bar shape which extends in a first horizontal direction (an X direction), and a first semiconductor pattern 120 exposed at the second opening portion OP2 may remain in a tapered shape where a thickness thereof in the vertical direction (the Z direction) decreases progressively in a direction distancing from the residual pattern 120R.

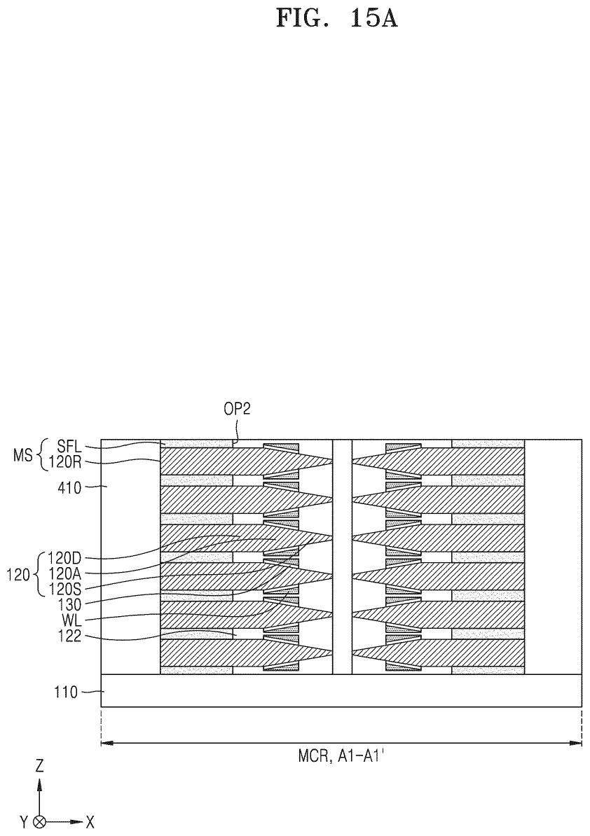

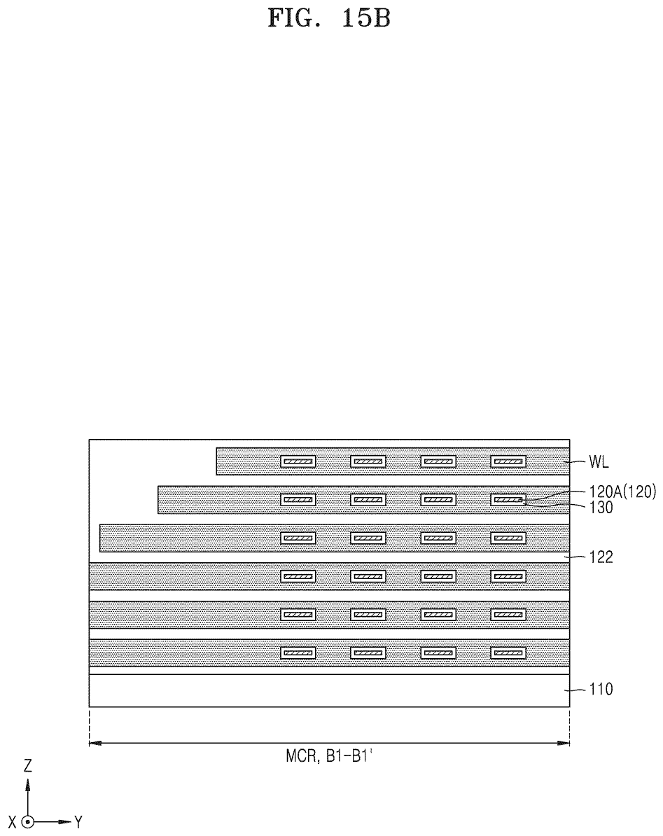

Referring to FIGS. 15A and 15B, in the memory cell region MCR, a gate insulation layer 130 and a word line WL may be sequentially formed on top surfaces, side surfaces, and bottom surfaces of the plurality of first semiconductor patterns 120, in the second opening portion OP2. For example, the gate insulation layer 130 may be conformally disposed to surround the plurality of first semiconductor patterns 120. That is, the gate insulation layer 130 may be formed in a shape where the first semiconductor pattern 120 has a certain slope in a tapered direction. The word line WL may be disposed to surround the plurality of first semiconductor patterns 120 and extend in the second horizontal direction (the Y direction), on the gate insulation layer 130.

In various example embodiments, as illustrated in FIG. 15A, a portion of each of the gate insulation layer 130 and the word line WL disposed at both end portions (for example, both end portions in the first horizontal direction (the X direction)) of each of the plurality of first semiconductor patterns 120 may be removed in the second opening portion OP2. In other example embodiments, a protection layer (not shown) covering the both end portions of each of the plurality of first semiconductor patterns 120 may be first formed in the second opening portion OP2, the gate insulation layer 130 and the word line WL each surrounding a center portion of each of the plurality of first semiconductor patterns 120 may be formed subsequently, the protection layer may be formed subsequently, and the both end portions of each of the plurality of first semiconductor patterns 120 may not be covered by the gate insulation layer 130 and the word line WL and may be again exposed.

Subsequently, a mold insulation layer 122 filling the inside of the second opening portion OP2 may be formed. In some example embodiments, the mold insulation layer 122 may be disposed between two word lines WL adjacent to each other in the vertical direction (the Z direction) and between two first semiconductor patterns 120 adjacent to each other in the vertical direction (the Z direction).

In various example embodiments, a word line pad WLP may be formed by removing a portion of the word line WL. The word line pad WLP may be disposed in a staircase shape, and for example, a word line pad WLP connected to one word line WL may be disposed apart from a word line pad WLP, connected to another word line WL disposed under the one word line WL, in the second horizontal direction (the Y direction).

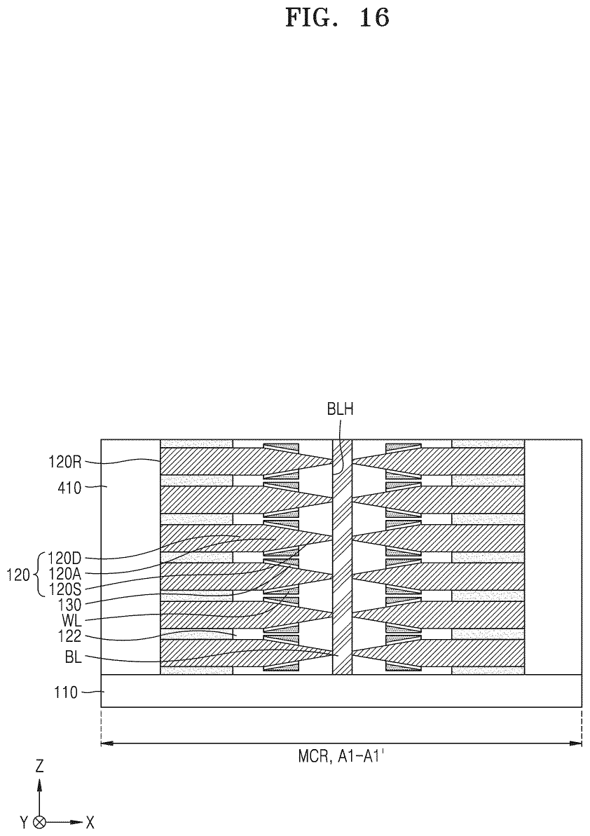

Referring to FIG. 16, in the memory cell region MCR, a bit line opening portion BLH may be formed by removing a portion of the first insulation layer 410, and a bit line BL may be formed in the bit line opening portion BLH.

In various example embodiments, as illustrated in FIG. 16, two first semiconductor patterns 120 may be disposed apart from each other in the first horizontal direction (the X direction) with the bit line BL therebetween, a first sidewall of one bit line BL may contact the first impurity region 120S of one first semiconductor pattern 120, and a second sidewall of the one bit line BL may contact the first impurity region 120S of another first semiconductor pattern 120. That is, two first semiconductor patterns 120 disposed at the same vertical level may be electrically connected to one bit line BL, but the inventive concepts are not limited thereto.

As described above, in the first semiconductor pattern 120, the channel region 120A and the first impurity region 120S may have a tapered shape where a width thereof in the vertical direction (the Z direction) narrows progressively toward the bit line BL. The tapered shape of the semiconductor pattern may improve electrical and structural stability of the semiconductor device.

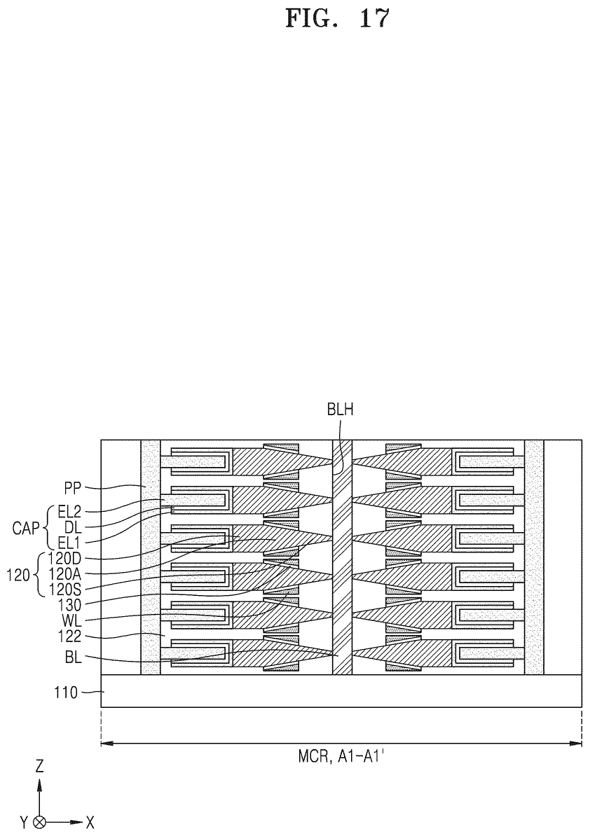

Referring to FIG. 17, the sacrificial mold layer SFL and the residual pattern 120R may be removed in the memory cell region MCR, and a cell capacitor CAP may be formed at a position at which each of the sacrificial mold layer SFL and the residual pattern 120R is removed.

In various example embodiments, the cell capacitor CAP may include a first electrode EL1, a capacitor dielectric layer DL, and a second electrode EL2. The first electrode EL1 may be electrically connected to the second impurity region 120D of the first semiconductor pattern 120 and may include an internal space which extends in the first horizontal direction (the X direction). The capacitor dielectric layer DL may be conformally disposed in the internal space, and the internal space may be filled by the second electrode EL2.

Subsequently, a plate electrode PP which is electrically connected to the second electrode EL2 and extends in the second horizontal direction (the Y direction) may be formed.

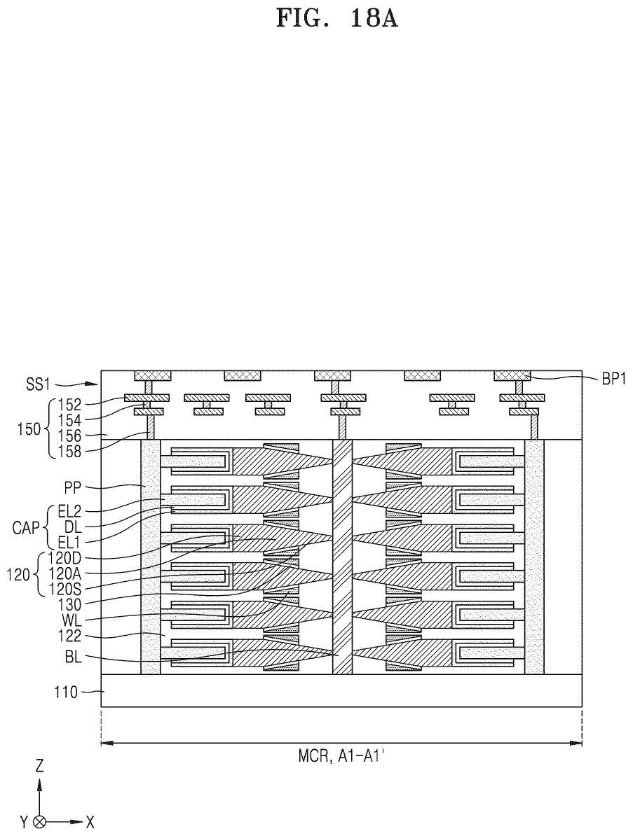

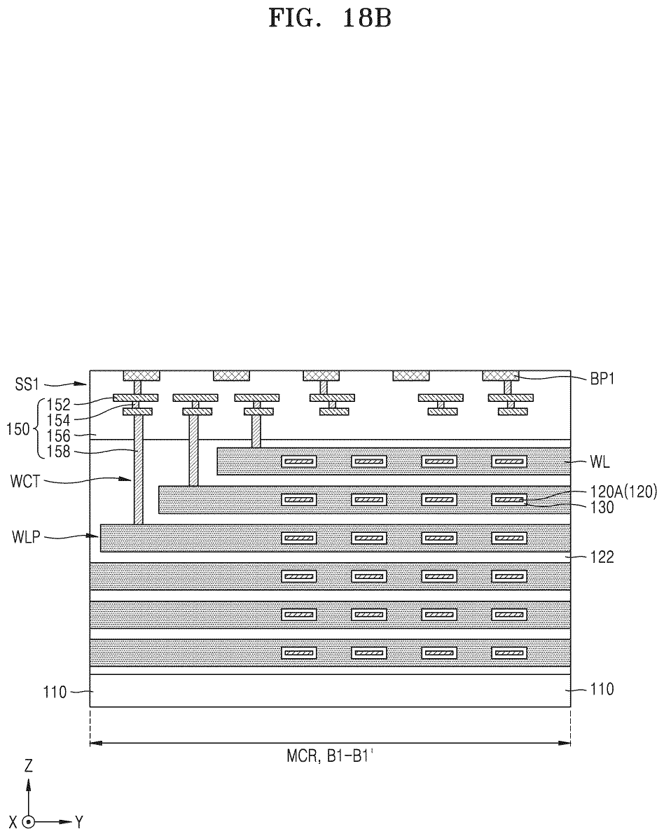

Referring to FIGS. 18A and 18B, an upper wiring structure 150 may be formed in the memory cell region MCR. The upper wiring structure 150 may include a wiring layer 152, a via 154, an insulation layer 156, and a contact 158. For example, the contact 158 may be electrically connected to the bit line BL, the word line WL, and the plate electrode PP. Subsequently, a first bonding pad BP1 disposed on the same plane as an uppermost surface of the insulation layer 156 may be formed on the upper wiring structure 150.

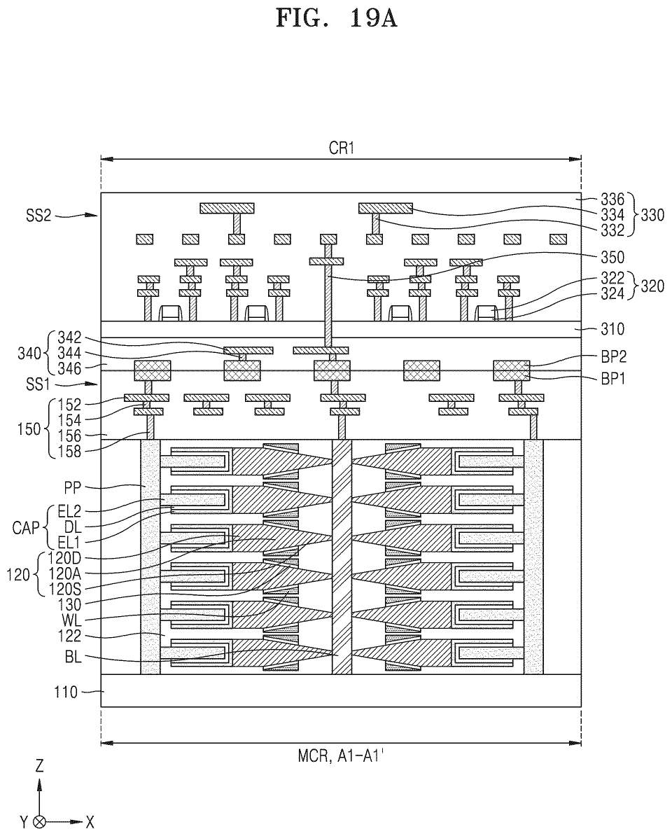

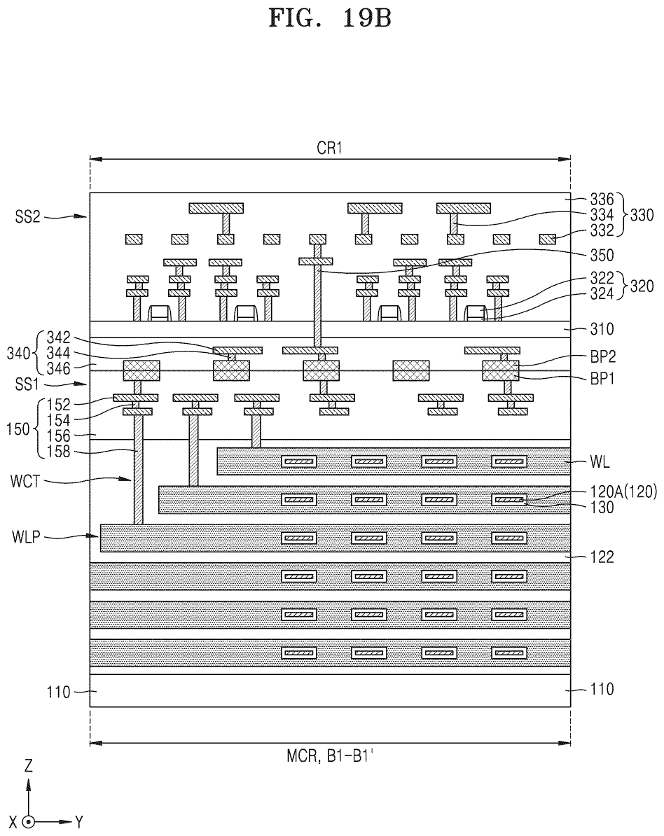

Referring to FIGS. 19A and 19B, a second stack structure SS2 may be prepared.

In various example embodiments, the second stack structure SS2 may include a second substrate 310, a peripheral circuit transistor 320 disposed on the second substrate 310, a front wiring structure 330 covering the peripheral circuit transistor 320 on a top surface of the second substrate 310, and a backside wiring structure 340 disposed on a bottom surface of the second substrate 310.

In various example embodiments, the peripheral circuit transistor 320 may be formed on a first surface (or a top surface) of the second substrate 310, the front wiring structure 330 may be formed on the first surface of the second substrate 310, a carrier substrate may be attached on the front wiring structure 330, and then, the second substrate 310 may be thinned by grinding a second surface (or a bottom surface) of the second substrate 310. Subsequently, the second stack structure SS2 may be finished by forming the backside wiring structure 340 and the second bonding pad BP2 on the second surface of the second substrate 310.

Subsequently, the second stack structure SS2 may be bonded to the first stack structure SS1, and at this time, the first bonding pad BP1 of the first stack structure SS1 may be bonded to the second bonding pad BP2 of the second stack structure SS2, and a top surface of the upper insulation layer 156 may be bonded to a bottom surface of the insulation layer 346.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Hereinabove, various example embodiments have been described in the drawings and the specification. Example embodiments have been described by using the terms described herein, but this has been merely used for describing the inventive concepts and has not been used for limiting a meaning or limiting the scope of the inventive concepts defined in the following claims. Therefore, it may be understood by those of ordinary skill in the art that various modifications and other equivalent embodiments may be implemented from the inventive concepts. Accordingly, the spirit and scope of the inventive concepts may be defined based on the spirit and scope of the following claims.

While the inventive concepts have been particularly shown and described with reference to embodiments thereof, it will be understood that various changes in form and details may be made therein without departing from the spirit and scope of the following claims.

What is claimed is:

1. A semiconductor memory device comprising:
a first stack structure including a memory cell region;
the memory cell region including a plurality of memory cells three-dimensionally arranged;
the plurality of memory cells including a plurality of cell capacitors;
a second stack structure including a core region at a position vertically overlapping the memory cell region; and
the core region electrically connected to the memory cell region,
wherein the first stack structure comprises
a first substrate,
a first semiconductor pattern on the first substrate in the memory cell region,
the first semiconductor pattern extending in a first direction parallel to a top surface of the first substrate,
a word line surrounding the first semiconductor pattern and the word line extending in a second direction, the second direction being parallel to the top surface of the first substrate,
a bit line connected to a first end portion of the first semiconductor pattern,
the bit line extending in a third direction perpendicular to the top surface of the first substrate, and
a thickness in the third direction of the first end portion of the first semiconductor pattern differs from a thickness in the third direction of a second end portion of the first semiconductor pattern, the second end portion being opposite the first end portion in the first direction.

2. The semiconductor memory device of claim 1, wherein the thickness in the third direction of the second end portion of the first semiconductor pattern is greater than the thickness in the third direction of the first end portion of the first semiconductor pattern.

3. The semiconductor memory device of claim 1, wherein each of the cell capacitors are connected to the second end portion of the first semiconductor pattern, and
each of the cell capacitors extend in the first direction.

4. The semiconductor memory device of claim 3, wherein the thickness of the second end portion of the first semiconductor pattern in the third direction is equal to a thickness of the cell capacitor in the third direction.

5. The semiconductor memory device of claim 1, wherein
the first semiconductor pattern comprises
a channel region,
a first impurity region, and
a second impurity region,
the channel region is between the first and second impurity region in the first direction,
the first impurity region is connected to the bit line by the first end portion of the first semiconductor pattern, and
the second impurity region is connected to the word line by the second end portion of the first semiconductor pattern.

6. The semiconductor memory device of claim 5, wherein the channel region and the first impurity region have a tapered shape such that a thickness thereof in the third direction decreases toward the bit line.

7. The semiconductor memory device of claim 6, wherein a thickness of each of the channel region and the first impurity region in the third direction is continuously changed.

8. The semiconductor memory device of claim 5, further comprising a gate insulation layer between the first semiconductor pattern and the word line,
wherein the gate insulation layer conformally surrounds the channel region.

9. The semiconductor memory device of claim 5, wherein
each of the cell capacitors comprise
a first electrode,
a capacitor dielectric layer, and
a second electrode, and
the first electrode defines an internal space electrically connected to the second impurity region of the first semiconductor pattern and the internal space of the first electrode extends in the first direction.

10. The semiconductor memory device of claim 9, wherein the capacitor dielectric layer is layered conformally in the internal space of the first electrode, and the internal space is further filled by the second electrode, and
the semiconductor memory device further comprises a plate electrode electrically connected to the second electrode, and the plate electrode extends in the third direction.

11. The semiconductor memory device of claim 1, wherein a width of the first semiconductor pattern is uniform in the second direction from the first end portion of the first semiconductor pattern to the second end portion of the first semiconductor pattern.

12. A semiconductor memory device comprising:
a first stack structure including a plurality of memory cells on a first substrate;
the plurality of memory cells arranged apart from each other in a vertical direction, the vertical direction being perpendicular to a top surface of the first substrate; and
a second stack structure on the first stack structure including a core region on a second substrate, the core region vertically overlapping each of the plurality of memory cells and electrically connected to the plurality of memory cells,
wherein the plurality of memory cells each comprise a plurality of first semiconductor patterns extending in a first direction, the first direction being parallel to the top surface of the first substrate,
each of the plurality of first semiconductor patterns comprise
a channel region,
a first impurity region, and
a second impurity region,
the channel region is between the first and second impurity regions in the first direction, and
a width of each of the first semiconductor patterns in a vertical direction decreases from the second impurity region, through the channel region, and through the first impurity region.

13. The semiconductor memory device of claim 12, wherein the first stack structure comprises:
a word line surrounding the plurality of first semiconductor patterns and extending in a second direction, the second direction being parallel to the top surface of the first substrate;
a bit line connected to first end portions of the plurality of first semiconductor patterns and the bit line extending in the vertical direction; and
a plurality of cell capacitors respectively connected to second end portions of the plurality of first semiconductor patterns.

14. The semiconductor memory device of claim 13, wherein a width of the second impurity region in the vertical direction is uniform, and
a width of each of the channel region and the first impurity region decreases in a direction distancing from a corresponding cell capacitor.

15. The semiconductor memory device of claim 13, wherein a thickness in the vertical direction of the second impurity region is equal to a thickness in the vertical direction of each of the plurality of cell capacitors.

16. The semiconductor memory device of claim 13, wherein
each of the plurality of cell capacitors comprises
a first electrode,
a capacitor dielectric layer, and
a second electrode,
the first electrode is electrically connected to the second impurity region of a corresponding one of the plurality of first semiconductor patterns, and
the second electrode is electrically connected to a plate electrode extending in the second direction.

17. The semiconductor memory device of claim 13, further comprising a gate insulation layer between a corresponding one of the plurality of first semiconductors pattern and the word line,
wherein the gate insulation layer conformally surrounds a tapered surface of the channel region.

18. The semiconductor memory device of claim 12, wherein a width of each of the plurality of first semiconductor patterns extending in a second direction is equal throughout the channel region, the first impurity region, and the second impurity region.

19. A semiconductor memory device comprising:
a first substrate;
a plurality of first semiconductor patterns on the first substrate extending in a first direction, the first direction being parallel to a top surface of the first substrate,
each of the plurality of first semiconductor patterns including
a first impurity region,
a second impurity region, and
a channel region, the channel region being between the first impurity region and the second impurity region;
a word line on at least a portion of each of the plurality of first semiconductor patterns and extending in a second direction, the second direction being parallel to the top surface of the first substrate;
a bit line extending in a third direction, the third direction being perpendicular to the top surface of the first substrate;
the bit line connected to first end portions of the plurality of first semiconductor patterns included in the first impurity region;
a plurality of cell capacitors respectively connected to second end portions of the plurality of first semiconductor patterns included in the second impurity region; and
a second substrate at a vertical level which is higher than the first substrate,
wherein a thickness in the third direction of the second impurity region is equal to a thickness in the third direction of each of the plurality of cell capacitors, and
the channel region and the first impurity region have a tapered shape where a thickness thereof in the third direction decreases towards the bit line.

20. The semiconductor memory device of claim 19, further comprising a gate insulation layer between the channel region and the word line,
wherein the gate insulation layer conformally surrounds a tapered surface of the channel region.
